(19) United States
(12) Patent Application Publication
(10) Pub. No.: US 2022/0308403 A1
(43) Pub. Date: Sep. 29, 2022

(54) ARRAY SUBSTRATE AND LCD DEVICE

(71) Applicant: Shenzhen China Star Optoelectronics Semiconductor Display Technology Co., Ltd., Shenzhen (CN)

(72) Inventor: Wu CAO, Shenzhen (CN)

(21) Appl. No.: 16/640,741

(22) PCT Filed: Dec. 27, 2019
(86) PCT No.: PCT/CN2019/129206

§ 371 Date: Feb. 21, 2020

(30) Foreign Application Priority Data
Dec. 16, 2019 (CN) 201911296682.4

(51) Int. Cl. G02F 1/1343; H01L 27/12; G02F 1/1362; G02F 1/1368

(52) U.S. Cl. CPC G02F 1/134309; H01L 27/1222; H01L 27/1244; G02F 1/136286; G02F 1/1368

(57) ABSTRACT

The present invention provides an array substrate and a liquid crystal display (LCD) device. The array substrate includes multiple pixel units arranged in an array. Each pixel unit includes a pixel electrode and a thin film transistor (TFT). The pixel electrode includes a primary-region pixel electrode and a secondary-region pixel electrode. The TFT includes a first TFT for controlling the primary-region pixel electrode and a second TFT for controlling the secondary-region pixel electrode. The primary-region pixel electrode and the secondary-region pixel electrode are arranged on a same side of the first TFT and the second TFT.

### 1. FIELD OF DISCLOSURE

The present embodiment relates to a field of display technology and in particular, to an array substrate and a liquid crystal display (LCD) device.

### 2. Description of Related Art

For large-sized thin film transistor liquid crystal display (TFT-LCD) televisions, vertical alignment liquid crystal displays (VA LCDs) are commonly used due to its wide viewing angle, high contrast ratios, and requiring no alignment friction.

In conventional VA-LCD technology, in order to have a better wide viewing angle experience, the number of pixel electrode domains is usually increased for improvement of, for example, chroma and viewing angle. For example, a primary region and a secondary region having different driving voltage differences are set, and the primary region and the secondary region each include 4 axisymmetric domains. A difference between front view and side view is reduced by spatial and liquid crystal orientation differentiation. Accordingly, a side-view color shit problem is improved. However, in such an eight-domain pixel structure, a thin film transistor device is generally added to adjust a voltage division ratio, which will cause a pixel aperture ratio/native transmittance to be limited. On the other hand, in order to prevent crosstalk risks, it is often necessary to add a DBS electrode to achieve electric field shielding, which further limits an increase in the aperture ratio.

### SUMMARY

The invention provides an array substrate and a liquid crystal display (LCD) device. A pixel region of the array substrate has a large aperture ratio.

In one aspect, the present invention provides an array substrate, comprising:

a plurality of scan lines arranged in a horizontal direction;

a plurality of data lines arranged in a vertical direction; and

a plurality of pixel units arranged in an array, wherein each of the pixel units comprises:

a pixel electrode comprising primary-region pixel electrode and a secondary-region pixel electrode; and

a thin film transistor (TFT) comprising a first TFT for controlling the primary-region pixel electrode and a second TFT for controlling the secondary-region pixel electrode;

wherein the primary-region pixel electrode and the secondary-region pixel electrode are disposed on a same side of the first TFT and the second TFT.

In the array substrate according to one embodiment of the present application, the first TFT comprises a first source in a U shape and a first drain in a strip shape, and one end of the first drain is inserted into a U-shaped opening of the first source; and

the second TFT comprises a second source in a U shape and a second drain in a strip shape, and one end of the second drain is inserted into a U-shaped opening of the second source;

wherein the U-shaped opening of the first source and the U-shaped opening of the second source are open toward a same direction.

In the array substrate according to one embodiment of the present application, the first source is electrically connected to one of the data lines, and the first drain is electrically connected to the primary-region pixel electrode; and the second source is electrically connected to the first source, and the second drain is electrically connected to the secondary-region pixel electrode.

In the array substrate according to one embodiment of the present application, in any one of the pixel units, the primary-region pixel electrode and the secondary-region pixel electrode are of a same polarity.

In the array substrate according to one embodiment of the present application, the pixel units in a same column receives a signal from one of the data lines.

In the array substrate according to one embodiment of the present application, the pixel electrodes in any column of the pixel units are of a same polarity, a first polarity, while the pixel electrodes in an adjacent column of the pixel units are of a second polarity, and the first polarity is opposite to the second polarity.

In the array substrate according to one embodiment of the present application, the primary-region pixel electrode and the secondary-region pixel electrode each include four domains, and a plurality of branch electrodes extending in four different directions are arranged in the four domains.

In the array substrate according to one embodiment of the present application, the branch electrodes extending in the four different directions comprises a first branch electrode, a second branch electrode, a third branch electrode, and a fourth branch electrode, an angle between the first branch electrode and a horizontal direction is 45°, an angle between the second branch electrode and the horizontal direction is 135°, an angle between the third branch electrode and the horizontal direction is −135°, and an angle between the fourth branch electrode and the horizontal direction is −45°.

In the array substrate according to one embodiment of the present application, a minimum distance between the primary-region pixel electrode and the secondary-region pixel electrode is greater than or equal to 2.5 micrometers.

In the array substrate according to one embodiment of the present application, the primary-region pixel electrode and the secondary-region pixel electrode are disposed adjacent to each other in a column direction.

In the array substrate according to one embodiment of the present application, a blank region is arranged inside the secondary-region pixel electrode, and the primary-region pixel electrode is disposed in the blank region.

The present invention further provides a liquid crystal display (LCD) device, comprising the array substrate mentioned above.

The present invention provides an array substrate. The pixel electrode in the array substrate has an eight-domain design, which includes a primary-region pixel electrode having four domains and a secondary-region pixel electrode having four domains. By arranging the primary-region pixel electrode and the secondary-region pixel electrode on the same side of the scan line (or the TFT switch), an aperture ratio of a pixel region is improved.

Specifically, in conventional eight-domain designs for the pixel electrode, the primary-region pixel electrode and the secondary-region pixel electrode are usually arranged on two sides of the scan line, so in the column direction, the primary-region pixel electrode and the secondary-region pixel electrode in a pixel unit are adjacent to each other. However, two adjacent pixel units are typically of opposite polarities. In other words, the primary-region pixel electrode in a pixel unit and the secondary-region pixel electrode in an adjacent pixel unit are of opposite polarities, Due to the opposite polarities, a wider dark strip appears between them. As a result, an aperture ratio is decreased. In the present invention, the eight-domain design for the pixel electrode avoids occurrence of a dark strip resulting from the opposite polarities of the adjacent pixel units. Also, the present invention avoids occurrence of a dark strip in the same pixel unit because the primary-region pixel electrode and the secondary-region pixel electrode in the same pixel unit are of the same polarity. Accordingly, an aperture ratio of a pixel region is effectively increased.

### BRIEF DESCRIPTION OF DRAWINGS

In order to more clearly illustrate the embodiments of the present disclosure or related art, figures which will be described in the embodiments are briefly introduced hereinafter. It is obvious that the drawings are merely for the purposes of illustrating some embodiments of the present disclosure, and a person having ordinary skill in this field can obtain other figures according to these figures without an inventive work.

FIG. 1 is a schematic structural view illustrating an array substrate according to one embodiment of the present invention;

FIG. 2 is a schematic view illustrating a rule of polarity arrangement of pixel units according to one embodiment of the present invention;

FIG. 3 is a schematic structural view illustrating a primary-region pixel electrode according to one embodiment of the present invention; and

FIG. 4 is a schematic view illustrating arrangement of the primary-region pixel electrode and a secondary-region pixel electrode according to one embodiment of the present invention.

### DETAILED DESCRIPTION OF EMBODIMENTS

Technical solutions of the present invention will be clearly and completely described below with reference to specific embodiments and the accompanying drawings. It is apparent that the embodiments are only some embodiments of the present invention, but not all of the embodiments. All other embodiments obtained by those skilled in the art based on the embodiments of the present invention without an inventive step are deemed to be within the protection scope of the present invention.

In the specification, it should be understood that the terms such as “central”, “longitudinal”, “lateral”, “length”, “width”, “thickness”, “above”, “below”, “front”, “rear”, “left”, “right”, “vertical”, “horizontal”, “top”, “bottom”, “inner”, “outer”, should be construed to refer to position relationship or the orientation based on the accompanying drawings. These terms are merely for ease of description and do not alone indicate or imply that the device or element referred to must be set up or operated in a specific orientation. Thus, the present invention is not limited by the directional terms. In addition, terms such as “first” and “second” are used for purposes of description and are not intended to indicate or imply relative importance or significance or impliedly indicate quantity of the technical feature referred to. Thus, the feature defined with “first” and “second” may explicitly or implicitly indicate inclusion of one or more this feature. In the description of the present application, “a plurality of” means two or more than two, unless specified otherwise.

In conventional vertical alignment liquid crystal displays (VA LCDs), in order to improve problems such as color shift, the pixel electrode is usually designed as an eight-domain structure which includes a primary-region pixel electrode with a four-domain structure and a secondary-region pixel electrode with a four-domain structure. In conventional techniques, the primary-region pixel electrode and secondary-region pixel electrode are usually disposed on two sides of a thin film transistor. This way, in an overall pixel arrangement, for pixel units in a same column, the secondary-region pixel electrode of the pixel unit of an Nth row is adjacent to the primary-region pixel electrode of the pixel unit of an (N+1)th row, and they have opposite polarities, and there is a wider dark strip between them. As a result, an aperture ratio of the pixel unit is decreased.

The inventor has found through optical simulation and experiments that, when adjacent pixel units have different polarities, a wide dark strip appears between them; and when adjacent pixel units are of the same polarity, the dark strip between them becomes narrow. The present invention improves the aperture ratio based on this principle, detailed as follows.

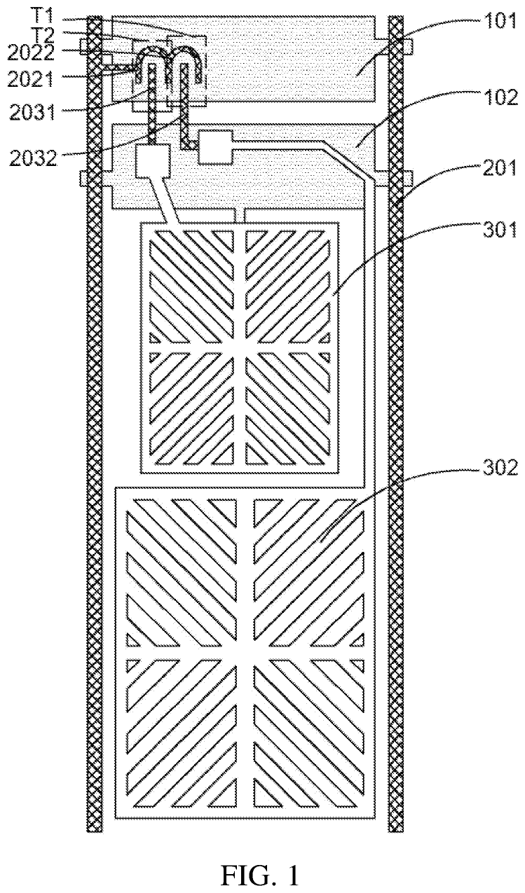

The present invention provides an array substrate. Please refer to FIG. 1 illustrating a structure of the array substrate, the array substrate comprising:

a plurality of scan lines 101 (only one is shown in the drawing) arranged in a horizontal direction for controlling an ON/OFF state of a thin film transistor (TFT);

a plurality of data lines 201 (only two are shown in the drawing) arranged in a vertical direction for sending signals to pixel units to determine a voltage of a pixel electrode, thereby controlling brightness of the pixel units; and

the pixel units arranged in an array, wherein each of the pixel units comprises:

a pixel electrode comprising a primary-region pixel electrode 301 and a secondary-region pixel electrode 302; and

the thin film transistor (TFT) comprising a first TFT T1 for controlling the primary-region pixel electrode 301 and a second TFT T2 for controlling the secondary-region pixel electrode 302;

wherein the primary-region pixel electrode 301 and the secondary-region pixel electrode 302 are disposed on a same side of the first TFT T1 and the second TFT T2.

In the array substrate of the present embodiment, for the pixel units in a same column, the secondary-region pixel electrode of the pixel unit of the Nth row is adjacent to the scan line or the TFT of the pixel unit of the (N+1)th row, instead of the pixel electrode being adjacent to the pixel electrode, thereby avoiding the occurrence of wide dark strips. Furthermore, in one pixel unit, the primary-region pixel electrode is adjacent to the secondary-region pixel electrode, but the primary-region pixel electrode and the secondary-region pixel electrode have the same polarity because they both receive signals from the same data line, so a dark strip appears between them is narrower, and an aperture ratio of the pixel unit is increased.

The first TFT T1 comprises a first source 2021 in a U shape and a first drain 2031 in a strip shape, and the first drain 2031 is inserted into a U-shaped opening of the first source 2021. The second TFT T2 comprises a second source 2022 in a U shape and a second drain 2032 in a strip shape, and the second drain 2032 is inserted into a U-shaped opening of the second source 2022. The U-shaped opening of the first source 2021 and the U-shaped opening of the second source 2022 are open toward a same direction.

The U-shaped opening of the first source 2021 and the U-shaped opening of the second source 2022 are open toward the same direction, so wiring is facilitated, and the primary-region pixel electrode and the secondary-region pixel electrode can be disposed on the same side of the TFT. It is also viable to use other designs which can arrange the primary-region pixel electrode and the secondary-region pixel electrode on the same side of the TFT.

Furthermore, each pixel unit further comprises a common electrode 102. The common electrode 102 and the scan line 101 are formed in a same film formation step and a same patterning step. A storage capacitance of the primary-region pixel electrode is formed in an area where the common electrode 102 overlaps an orthogonal projection of the primary-region pixel electrode. A storage capacitance of the secondary-region pixel electrode is formed in an area where the common electrode 102 overlaps an orthogonal projection of the secondary-region pixel electrode.

The first source 2021 is electrically connected to one of the data lines 201, and the first drain 2031 is electrically connected to the primary-region pixel electrode 301. The second source 2022 is electrically connected to the first source 2021, and the second drain 2032 is electrically connected to the secondary-region pixel electrode 302.

The second source 2022 and the first source 2021 are electrically connected to each other and receive same data signals, so the primary-region pixel electrode 301 and the secondary-region pixel electrode 302 are of the same polarity.

The pixel units in the same column receive signals from the same one of the data lines. In other words, the pixel electrodes of the pixel units in the same column are of the same polarity.

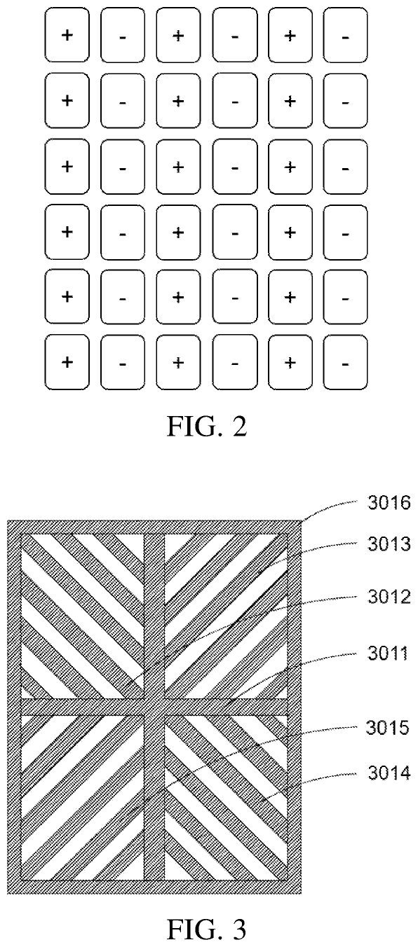

Any two adjacent data lines send different voltage signals, so the pixel units of adjacent two columns are of different polarities. In detail, the pixel electrodes in the pixel unit of any column are of a same polarity, i.e., a first polarity, while the pixel electrodes in the pixel unit of an adjacent column are of a second polarity. The first polarity is opposite to the second polarity. The pixel electrodes in the pixel units arranged in an array present a rule as shown in FIG. 2.

The primary-region pixel electrode and the secondary-region pixel electrode each include four domains, and a plurality of branch electrodes extending in four different directions are arranged in the four domains.

A description is provided below by taking the primary-region pixel electrode 301 as an example.

Please refer to FIG. 3. The primary-region pixel electrode 301 comprises:

a trunk electrode 3011 having a cross shape and dividing the pixel unit into four domains;

a border electrode 3016, wherein the boarder electrode 3016 is a rectangular frame and electrically connected to four ends of the trunk electrode 3011;

a plurality of branch electrodes comprising a first branch electrode 3012, a second branch electrode 3013, a third branch electrode 3014, and a fourth branch electrode 3015 respectively arranged in the four domains. The branch electrodes extending in the four domains extend in four different directions. One end of the branch electrode is electrically connected to the trunk electrode 3011, and the other end of the branch electrode is electrically connected to the border electrode 3016.

In a preferable embodiment, an angle between the first branch electrode 3012 and a horizontal direction is 45°, an angle between the second branch electrode 3013 and the horizontal direction is 135°, an angle between the third branch electrode 3014 and the horizontal direction is −135°, and an angle between the fourth branch electrode 3015 and the horizontal direction is −45°.

In the present embodiment, a minimum distance between the primary-region pixel electrode 301 and the secondary-region pixel electrode 302 is greater than or equal to 2.5 micrometers. A safety distance is set to prevent interference between the primary-region pixel electrode 301 and the secondary-region pixel electrode 302, so that short circuits therebetween are prevented from being caused by particles generated during a manufacturing process.

In the present embodiment, the primary-region pixel electrode 301 and the secondary-region pixel electrode 302 are disposed adjacent to each other in a column direction.

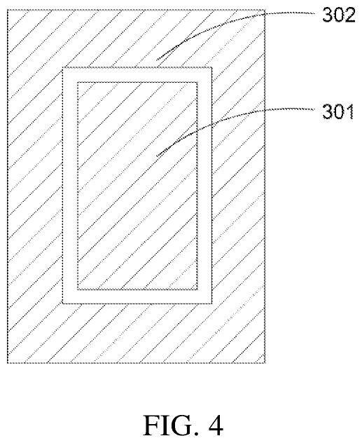

It should be noted that the primary-region pixel electrode 301 and the secondary-region pixel electrode 302 can be arranged in any other suitable manner beside the mutually adjacent manner described above. For example, they can be arranged in a manner shown in FIG. 4. That is, a blank region is arranged inside the secondary-region pixel electrode 302, and the primary-region pixel electrode 301 is disposed in the blank region. This way, the primary-region pixel electrode and the secondary-region pixel electrode optimize display performance by having a shared region.

The positive and negative polarities of the pixel electrodes mentioned in the application are defined by a potential relative to a potential of the common electrode 102 of a color filter substrate. Normally, the potential of the common electrode 102 in the color filter substrate ranges from 6V to 7V. When the potential of the pixel electrode is less than the potential of the common electrode 102 of the color filter substrate, and then the pixel electrode is of negative polarity. On the contrary, when the potential of the pixel electrode is greater than the potential of the common electrode 102 of the color filter substrate, and then the pixel electrode is of positive polarity.

The present invention further provides a liquid crystal display (LCD) device according to another embodiment of the present invention. The LCD device comprises the array substrate mentioned above.

It should be noted that the above-mentioned embodiment of the array substrate only describes the above-mentioned structure. It can be understood that, except the above-mentioned structure, the display panel of the present invention can also include other necessary structures such as a shared thin film transistor (voltage division is used to achieve a voltage difference between the primary-region pixel electrode and the secondary-region pixel electrode), and a DBS electrode (an indium tin oxide common electrode, or an ITO com electrode for short, on one side of the array substrate); however, the present invention is not limited in this regard.

The array substrate and the liquid crystal display device of the present invention have been described in detail above. The embodiments of the present application have been described in detail above to illustrate the working principles of the present application. The above description is only provided for ease of understanding of the present invention and its main ideas. Those skilled in the art will be able to modify the embodiments and their applications. All such changes/modifications should be deemed to be within the protection scope of the present application. In conclusion, the content of the present disclosure should not be construed as limiting the present invention.

What is claimed is:

1. An array substrate, comprising:
a plurality of scan lines arranged in a horizontal direction;
a plurality of data lines arranged in a vertical direction; and
a plurality of pixel units arranged in an array, wherein each of the pixel units comprises:
a pixel electrode comprising primary-region pixel electrode and a secondary-region pixel electrode; and
a thin film transistor (TFT) comprising a first TFT for controlling the primary-region pixel electrode and a second TFT for controlling the secondary-region pixel electrode;
wherein the primary-region pixel electrode and the secondary-region pixel electrode are disposed on a same side of the first TFT and the second TFT.

2. The array substrate according to claim 1, wherein the first TFT comprises a first source in a U shape and a first drain in a strip shape, and one end of the first drain is inserted into a U-shaped opening of the first source; and
the second TFT comprises a second source in a U shape and a second drain in a strip shape, and one end of the second drain is inserted into a U-shaped opening of the second source;
wherein the U-shaped opening of the first source and the U-shaped opening of the second source are open toward a same direction.

3. The array substrate according to claim 2, wherein the first source is electrically connected to one of the data lines, and the first drain is electrically connected to the primary-region pixel electrode; and the second source is electrically connected to the first source, and the second drain is electrically connected to the secondary-region pixel electrode.

4. The array substrate according to claim 3, wherein in any one of the pixel units, the primary-region pixel electrode and the secondary-region pixel electrode are of a same polarity.

5. The array substrate according to claim 1, wherein the pixel units in a same column receives a signal from one of the data lines.

6. The array substrate according to claim 5, wherein the pixel electrodes in any column of the pixel units are of a same polarity, a first polarity, while the pixel electrodes in an adjacent column of the pixel units are of a second polarity, and the first polarity is opposite to the second polarity.

7. The array substrate according to claim 1, wherein the primary-region pixel electrode and the secondary-region pixel electrode each include four domains, and a plurality of branch electrodes extending in four different directions are arranged in the four domains.

8. The array substrate according to claim 7, wherein the branch electrodes extending in the four different directions comprises a first branch electrode, a second branch electrode, a third branch electrode, and a fourth branch electrode, an angle between the first branch electrode and a horizontal direction is 45°, an angle between the second branch electrode and the horizontal direction is 135°, an angle between the third branch electrode and the horizontal direction is −135°, and an angle between the fourth branch electrode and the horizontal direction is −45°.

9. The array substrate according to claim 1, wherein a minimum distance between the primary-region pixel electrode and the secondary-region pixel electrode is greater than or equal to 2.5 micrometers.

10. The array substrate according to claim 9, wherein the primary-region pixel electrode and the secondary-region pixel electrode are disposed adjacent to each other in a column direction.

11. The array substrate according to claim 9, wherein a blank region is arranged inside the secondary-region pixel electrode, and the primary-region pixel electrode is disposed in the blank region.

12. A liquid crystal display (LCD) device, comprising the array substrate of claim 1.
